(19) United States
(12) Patent Application Publication
(10) Pub. No.: US 2009/0021897 A1
(43) Pub. Date: Jan. 22, 2009

(54) ASSEMBLY WITH A HOUSING

(76) Inventors: Steffen Katzenberger, Bad Liebenzell (DE); Cornelius Liebenow, Leinfelden-Echterdingen (DE); Rainer Glauning, Aichtal-Groetzingen (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/175,535

(22) Filed: Jul. 18, 2008

(30) Foreign Application Priority Data
Jul. 18, 2007 (DE) 10 2007 033 427.5

(51) Int. Cl. H05K 7/00

(52) U.S. Cl. 361/679

(57) ABSTRACT

An assembly with a housing, having a storage cell with two electrical poles, in which the storage cell is retained in the housing, with two electric lines, and each line is connected to one of the electrical poles, and the two lines are extended to two electrical contacts, having a protection device, which is disposed in the current flow of at least one of the two lines, and the protection device is disposed outside the storage cell in the housing, and the protection device protects the storage cell against overheating and/or excess current.

### CROSS-REFERENCE TO RELATED APPLICATIONS

This application is based on German Patent Application No. 10 2007 033 427.5 filed on Jul. 18, 2007, upon which priority is claimed.

### BACKGROUND OF INVENTION

1. Field of the Invention

The invention relates to an assembly with a housing, having a chargeable storage cell and an assembly with a housing, having a chargeable storage cell and a second housing of an electrically operable device.

2. Description of the Prior Art

Rechargeable battery packs are used in modern handheld power tools, for instance, in order to supply current to the power tool in cordless fashion and enable mobile operation. Such battery packs comprise one or more electrically interconnected storage cells, which store electrical energy, and the storage cells can heat up severely both during discharging in normal operation and during recharging, which in an extreme case can cause damage to the battery pack. It is therefore known to measure the temperature of a battery pack, in order to prevent such thermal overloads. To that end, a temperature sensor, such as a so-called NTC, is used, which is secured to an individual cell by means of a thermally conductive adhesive strip. If a predetermined maximum temperature is exceeded, then in the simplest case the operation or the charging procedure, as applicable, can be discontinued to prevent overheating.

### OBJECT AND SUMMARY OF THE INVENTION

The object of the invention is to furnish an assembly, having a housing, with at least one chargeable storage cell, in which the storage cell can be protected against overheating or excess current more precisely and individually.

One advantage of the assembly is that the protection device is disposed outside the storage cell in the housing. In this way, it is possible to adapt and optionally replace the protection device individually.

A further advantage of the assembly is that the protection device is disposed in the housing of the electrical device, and thus an individual adaptation to the electrical device is made possible.

In one embodiment of the invention, the protection device is embodied as a reversible switch element, such as a PTC resistor. In this way, it is possible to use the protection function for the storage cell without damaging or destroying the protection device.

In a further embodiment, the protection device is embodied as an irreversible switch element. In this way, it is possible to put the assembly out of operation for a relatively long time, and replacing the irreversible switch element can be possible in order to make the assembly ready for use again.

In a further embodiment, one reversible and one irreversible switch element are connected in series. In this way, it is possible to furnish a dual protection function with different intended purposes.

Advantageously, the protection device is suitable for protecting a chargeable storage cell that has lithium ions; the storage cells used are relatively insensitive to overheating and excess voltage. For example, storage cells based on lithium-metal phosphate are used.

### BRIEF DESCRIPTION OF THE DRAWINGS

The invention will be better understood and further objects and advantages thereof will become more apparent from the ensuing detailed description of preferred embodiments taken in conjunction with the drawings, in which:

FIG. 1 shows an assembly with a housing, in the form of a battery pack;

FIG. 2 shows an electrical device with a battery pack;

FIG. 3 shows further dispositions of the protection devices; and

FIG. 4 shows additional dispositions of the protection device.

### DESCRIPTION OF THE PREFERRED EMBODIMENTS

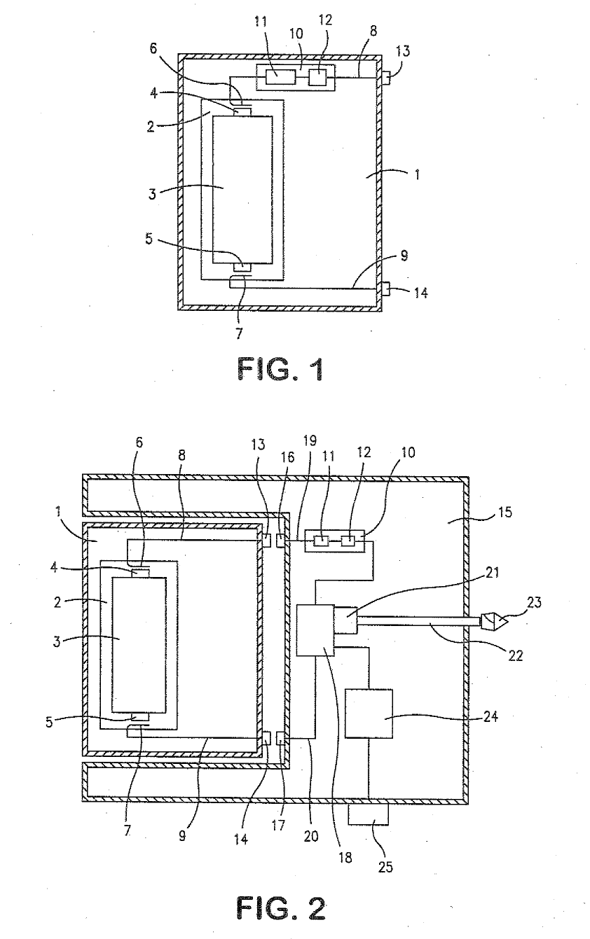

FIG. 1 in a schematic view shows a housing 1 with a receiving chamber 2, in which a storage cell 3 is disposed. On opposed ends, the storage cell 3 has a first pole 4 and a second pole 5. In the exemplary embodiment shown, the first pole 4 is embodied as the positive pole and the second pole 5 is embodied as here the negative pole. In a preferred embodiment, the rechargeable storage cell is embodied as a lithium ion storage cell, and an anode (negative) of carbon and a cathode (positive) with lithium-metal phosphate, in particular lithium-iron phosphate, are for instance used. On charging of the storage cell, lithium ions are bound in the anode (negative), and on discharging, the bound lithium ions are released to an electrolyte of the storage cell. The lithium ions are then bound on the cathode (positive). The cathode can have one of the materials having the general chemical composition of LiₓMPO₄, where M is selected from the group comprising Mn, Fe, Ni and CO, and x has a value between 0 and 1. Preferably, the compound has an olivine structure. The first pole 4 is in direct contact with a first inner contact 6 that is secured in the housing 1. The second pole 5 is in direct contact with a second inner contact 7, which is secured to the housing 1. The first inner contact 6 is connected to a first line 8 that electrically conductively connects the first inner contact 6 to a first outer contact 13. The first outer contact 13 is embodied on a side wall of the housing 1. The first line 8 has a protection device 10, through which the current flow of the first line 8 is carried. The second inner contact 7 is connected electrically conductively to a second outer contact 14 via a further first line 9. The second outer contact 14 is embodied on the same side of the housing 1 as the first outer contact 13.

In the exemplary embodiment shown, the protection device 10 has one reversible switch element 11 and one irreversible switch element 12. The reversible switch element 11 and the irreversible switch element 12 are connected in series. Depending on the embodiment selected, the protection device 10 may also have either only one reversible switch element 11 or only one irreversible switch element 12. The irreversible switch element 12 has the function of irreversibly interrupting the current flow in the line 8 if the temperature in the region of the irreversible switch element 12 exceeds a defined limit temperature, or if a defined limit current is exceeded. On reaching the defined limit temperature or the defined limit current, the irreversible switch element 12 interrupts the current conduction through the protection device 10. Thus the first pole 4 of the storage cell 3 is irreversibly disconnected from the first outer contact 13. By replacing the irreversible switch element 12, the electrically conductive connection between the first pole 4 and the first outer contact 13 can be restored. For instance, the irreversible switch element 12 can be embodied in the form of a fuse. Depending on the embodiment selected, the fuse is inserted into a contact receptacle and can be replaced as needed by a fuse with a different limit current value or a different limit temperature. A fuse that has burned through can also be replaced by a new, electrically conductive fuse.

The reversible switch element 11 has the function of reversibly interrupting the electrical conductivity of the reversible switch element 11 beyond a defined limit temperature and/or beyond a defined limit current. If the temperature falls below the limit temperature again and/or the current falls below the limit current again, then the electrical conductivity of the reversible switch element 11 is restored. In this way, depending on the temperature of the reversible switch element 11 and/or depending on the current flow through the reversible switch element 11, the first pole 4 of the storage cell 3 is reversibly disconnected from the first outer contact 13.

A PTC resistor can for instance be used as the reversible switch element. A PTC resistor is a resistor in which the resistance increases with increasing temperature and abruptly increases beyond a defined limit temperature, so that its electrical current flow in the sense of supplying current is no longer possible beyond the limit temperature. For instance, the limit temperature can be approximately SOC. Depending on the selected embodiment, the limit temperature at which the reversible switch element 11 reversibly interrupts the current flow can also be between 80° C. and 110° C. The reversible switch element 11 and/or the irreversible switch element 12 can be integrated electrically conductively with the first line 8 by way of plug contacts in the protection device 10. In this way, the reversible switch element 11 and/or the irreversible switch element 12 can be replaced easily as needed. Depending on the selected embodiment, soldered points can also be provided for connecting the irreversible switch element 12 and/or the reversible switch element 11 into the current flow of the first line 8.

In a preferred embodiment, the irreversible switch element 12 has a higher limit temperature than the reversible switch element 11. Moreover, in a further embodiment, the irreversible switch element 12 has a higher limit current than the reversible switch element 11.

Depending on the selected embodiment, the reversible switch element 11 and/or the irreversible switch element 12 is coupled thermally to the storage cell 3; the reversible switch element 11 and the irreversible switch element 12 are not located directly on the storage cell 3 but rather in the housing 1. As a coupling, a thermally conductive metal sheet or thermally conductive paste can be used. Moreover, depending on the selected embodiment, more than one storage cell, which are connected parallel or in series, can be provided in the housing. The protection device 10 has the function of protecting the storage cell against operating states at which risks begin for the storage cell and/or for the user of the storage cell. The assembly in accordance with FIG. 1 is a battery pack. An unwanted operating state can be both overcharging of the storage cell and discharging of the storage cell with an overly high current. An unwanted operating state can also be one in which the storage cell experiences an excessive load, with attendant rapid aging of the storage cell. The protection device 10 can furthermore have the unction of protecting the storage cell against operation at an overly high temperature. The storage cell can be embodied in particular in the form of a lithium ion cell, whose cathode (positive) contains phosphate. The protection device 10, in the selected embodiment, is not integrated with the storage cell but rather is disposed in the housing. Depending on the selected embodiment, the reversible switch element 11 and/or the irreversible switch element 12 is disposed replaceably in the housing 1, so that an optimal adaptation and selection of the reversible switch element 11 and/or the irreversible switch element 12 with regard to the operating states of the storage cell and the appropriate use of the storage cell can be made. In addition to the protection device 10 described, a temperature protection circuit in the form of a PTC resistor may also be embodied on the storage cell.

The protection device can for instance additionally serve to protect the storage cell against incorrect charging, such as applying an overly high voltage or failure on the part of the charger to recognize that charging has ended. In addition, in the event of failure of the reversible switch element 11, the irreversible switch element 12 can additionally serve to securely protect the storage cell against excessive current and/or excessive temperature.

FIG. 2 shows a further embodiment, in which the housing 1, with the first and second outer contacts 13, 14, is in electrical contact with a third and fourth outer contact 16, 17 of a second housing 15. In the embodiment shown, no protection device 10 is provided in the current flow of the first line 8 of the housing 1, but the first inner contact 6 is connected electrically conductively with the first outer contact 13 via the first line 8. In the second housing 15, an electrically operable device is embodied, such as a cordless screwdriver or a cordless power drill. For that purpose, an electric motor 18 is provided, which with a first electrical terminal is connected electrically conductively to the third outer contact 16 via a second line 19. The protection device 10 is disposed in the current flow of the second line 19. In addition, a second electrical terminal of the electric motor 18 is in contact with the fourth outer contact 17 via a further second line 20. The electric motor 18 is also connected to a rotatable final control element 22 via a gear 21. A drill 23 or screwdriver bit is secured to the rotatable final control element 22.

The motor 18 is connected to a control unit 24, which is in electrical contact with a user control unit 25. The user control unit 25 can be embodied as a push button. As a function of the actuation of the user control unit 25, the control unit 24 controls the power of the motor 18 and thus the rotary speed of both the final control element 22 and the drill 23.

As in the exemplary embodiment of FIG. 1, the protection device 10 has one reversible switch element 11 and/or one irreversible switch element 12. The reversible switch element 11 and the irreversible switch element 12 are disposed in the same way and embodied in the same way as in the embodiment of FIG. 1.

Depending on the selected embodiment, the limit temperature and/or the limit current of the reversible switch element 11 and/or of the irreversible switch element 12 can have different values than in the housing 1, because of their disposition in the second housing 15.

Depending on the selected embodiment, a charger, instead of the electrical device, can also be embodied in the second housing 15.

The protection device 10 can be disposed either in the first line, as shown in FIG. 1, or in the further second line 9. Moreover, depending on the embodiment, it can be possible to dispose the reversible switch element 11 in the first line 8 and the irreversible switch element 12 in the second line 9. In a further embodiment, the irreversible switch element 12 can also be disposed in the first line 8 and the reversible switch element 11 in the second line 9.

In the embodiment of FIG. 2, in which the protection device 10 is disposed in the second housing 15, the protection device 10 can also be disposed in the further second line 20. Depending on the selected embodiment, the reversible switch element 1 can be disposed in the second line 19, and the irreversible switch element 12 can be disposed in the further second line 20. Moreover, the irreversible switch element 12 can be disposed in the second line 19, and the reversible switch element 11 can be disposed in the further second line 20.

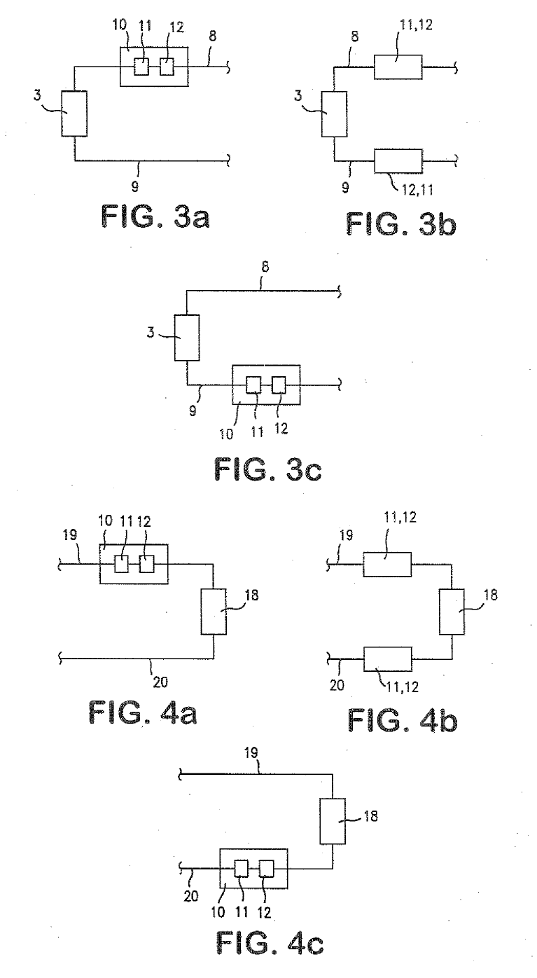

FIGS. 3A, 3B and 3C show the various possible dispositions of the reversible switch element 11 and irreversible switch element 12 in the housing 1.

FIGS. 4A, 4B and 4C show the various possible dispositions of the reversible switch element 11 and the irreversible switch element 12 in the second housing 15, in a schematic view.

Depending on the selected embodiment the protection device can be disposed partly in the housing 1 and partly in the second housing 15.

The foregoing relates to preferred exemplary embodiments of the invention, it being understood that other variants and embodiments thereof are possible within the spirit and scope of the invention, the latter being defined by the appended claims.

We claim:

1. An assembly comprising:
a housing;
at least one chargeable storage cell with two electrical poles, the storage cell being disposed in the housing;
two electric lines, each electrical line being connected to one of the electrical poles;
two electrical contacts disposed on the housing, each electrical line extending to one of the electrical contacts; and
a protection device disposed in the current flow of at least one of the two electrical lines and outside the storage cell in the housing, wherein the protection device protects the storage cell against overheating and/or excess current.

2. An assembly comprising:
a first housing;
at least one chargeable storage cell with two electrical poles, the storage cell being disposed in the first housing;
two electric lines, each electrical line being connected to one of the electrical poles;
two electrical contacts disposed on the first housing, each electrical line extending to one of the electrical contacts;
a second housing of an electrically operable device electrically connected to the first housing;
two additional electrical contacts disposed on the second housing, which are electrically conductively connected to the contacts disposed on the first housing;
two second lines connected to an electrical consumer and to the two additional contacts; and
a protection device disposed in the second housing and in the current flow of at least one of the two second lines, wherein the protection device protects the storage cell against overheating and/or excess current.

3. The assembly as defined by claim 1, wherein the protection device has a reversible switch element, which at a defined limit temperature limits the current flow.

4. The assembly as defined by claim 2, wherein the protection device has a reversible switch element, which at a defined limit temperature limits the current flow.

5. The assembly as defined by claim 3, wherein the reversible switch element is embodied as a PTC resistor with a positive thermal resistance, at which, beyond a defined limit temperature, the resistance increases greatly and substantially blocks the current flow through the PTC resistor.

6. The assembly as defined by claim 4, wherein the reversible switch element is embodied as a PTC resistor with a positive thermal resistance, at which, beyond a defined limit temperature, the resistance increases greatly and substantially blocks the current flow through the PTC resistor.

7. The assembly as defined by claim 1, wherein the protection device has an irreversible switch element, which at a defined limit temperature irreversibly interrupts the current flow through the switch element.

8. The assembly as defined by claim 2, wherein the protection device has an irreversible switch element, which at a defined limit temperature irreversibly interrupts the current flow through the switch element.

9. The assembly as defined by claim 3, wherein the protection device has an irreversible switch element, which at a defined limit temperature irreversibly interrupts the current flow through the switch element.

10. The assembly as defined by claim 4, wherein the protection device has an irreversible switch element, which at a defined limit temperature irreversibly interrupts the current flow through the switch element.

11. The assembly as defined by claim 1, wherein the protection device has an irreversible switch element, which at a defined limit temperature interrupts the current flow through the irreversible switch element.

12. The assembly as defined by claim 7, wherein the switch element is embodied as a fuse.

13. The assembly as defined by claim 11, wherein the switch element is embodied as a fuse.

14. The assembly as defined by claim 1, wherein the protection device (10) has one reversible and one irreversible switch element (11, 12), which are connected in series.

15. The assembly as defined by claim 2, wherein the protection device (10) has one reversible and one irreversible switch element (11, 12), which are connected in series.

16. The assembly as defined by claim 1, wherein the storage cell has a cathode whose structure is LiₓMPO₄, where M is selected from the group comprising Mn, Fe, Ni and CO, and x has a value between 0 and 1.

17. The assembly as defined by claim 2, wherein the storage cell has a cathode whose structure is LiₓMPO₄, where M is selected from the group comprising Mn, Fe, Ni and CO, and x has a value between 0 and 1.

18. The assembly as defined by claim 16, wherein the cathode of the storage cell at least partially has lithium-iron phosphate.

19. The assembly as defined by claim 1, wherein the protection device has an irreversible switch element, which at a defined current intensity limits the current flow.

20. The assembly as defined by claim 2, wherein the protection device has an irreversible switch element, which at a defined current intensity limits the current flow.
